(19) United States
(12) Patent Application Publication
(10) Pub. No.: US 2012/0069506 A1
(43) Pub. Date: Mar. 22, 2012

(54) ELECTRONIC DEVICE

(75) Inventors: Chih-Chang Lai, Taichung City (TW); Hsiao-Hui Liao, Taichung City (TW); Ting-Yu Chang, Kaohsiung City (TW)

(73) Assignees: WINTEK CORPORATION, Taichung City (TW); DONGGUAN MASSTOP LIQUID CRYSTAL DISPLAY CO., LTD., Dongguan City (CN)

(21) Appl. No.: 13/225,150

(22) Filed: Sep. 2, 2011

(30) Foreign Application Priority Data
Sep. 20, 2010 (TW) 99131881

(51) Int. Cl. H05K 7/00

(52) U.S. Cl. 361/679.01

(57) ABSTRACT

An electronic device is provided. The electronic device includes a transparent glass substrate, an inductive charge element and a power storage element. The inductive charge element includes a transparent conductive coil and a transparent protective layer. The transparent conductive coil disposed on the transparent glass substrate is a spiral structure. The transparent protective layer covers the transparent conductive coil. The power storage element is electrically connected to the inductive charge element.

This application claims the benefit of Taiwan application Serial No. 099131881, filed Sep. 20, 2010, the subject matter of which is incorporated herein by reference.

### BACKGROUND OF THE INVENTION

1. Field of the Invention

The invention relates in general to an electronic device, and more particularly to an electronic device with a power storage element.

2. Description of the Related Art

With the advance and innovation of high technology, electronic products are widely used in people's everyday life. Electronic products, such as mobile phone, digital camera, personal digital assistant and Walkman, having the features of lightweight, slimness and compactness, have won great popularity. However, hand-held electronic devices must consider the duration of power supply, and the user will find it extremely inconvenient when going outside and the charger is not available.

Despite there are wireless chargers available in the market for resolving the problem of power supply, these wireless chargers must be attached or added to the electronic device. These wireless chargers have the disadvantages such as increasing the thickness of the hand-held electronic devices, occupying more space and increasing additional weight, and are thus not in line with the market requirements of lightweight, slimness and compactness.

### SUMMARY OF THE INVENTION

The invention is directed to an electronic device in which the inductive charge element is directly fixed on the transparent glass substrate of the electronic device by a transparent conductive coil.

According to one aspect of the present invention, an electronic device is provided. The electronic device includes a transparent glass substrate, an inductive charge element and a power storage element. The inductive charge element includes a transparent conductive coil and a transparent protective layer. The transparent conductive coil disposed on the transparent glass substrate is a spiral structure. The transparent protective layer covers the transparent conductive coil. The power storage element is electrically connected to the inductive charge element.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 shows a top view of an electronic device according to a first embodiment of the invention;

FIG. 2 shows a cross-sectional view of the electronic device of FIG. 1 viewed along a dotted line A-A′;

FIG. 3 shows a cross-sectional view of an electronic device according to a second embodiment of the invention;

FIG. 4 shows a top view of an electronic device according to a third embodiment of the invention; and

FIG. 5 shows s a cross-sectional view of the electronic device of FIG. 4 viewed along a dotted line C-C′.

### DETAILED DESCRIPTION OF THE INVENTION

A number of embodiments are disclosed below for elaborating the invention. However, the embodiments of the invention are for detailed descriptions only, not for limiting the scope of protection of the invention. Furthermore, unnecessary elements are omitted in the accompanying diagrams of the embodiments for highlighting the technical features of the invention.

### First Embodiment

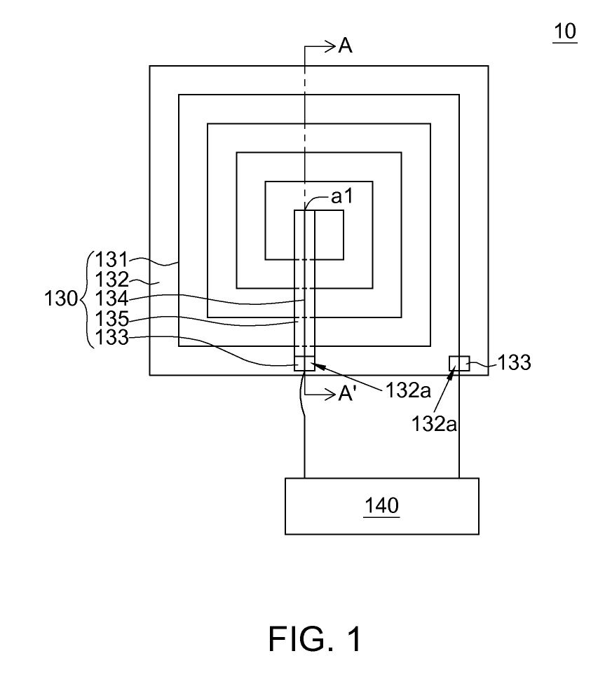

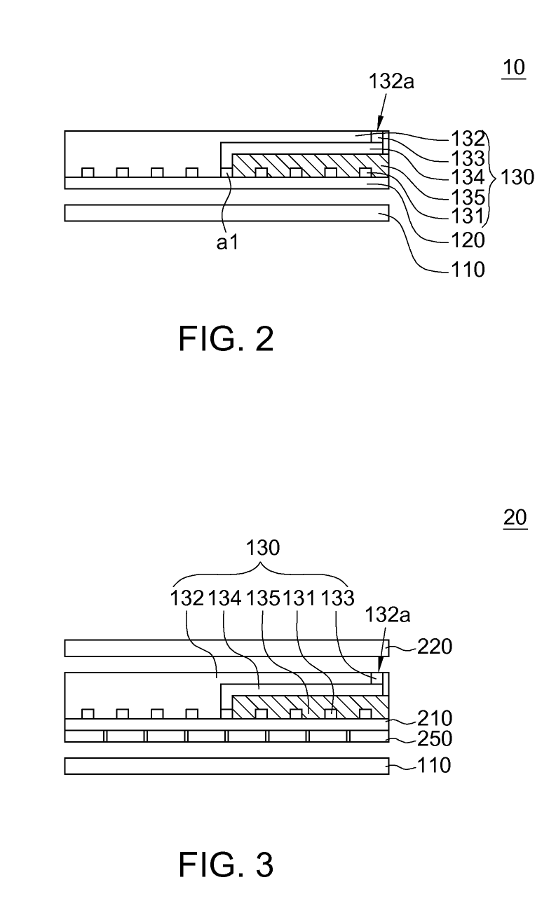

Refer to FIG. 1 and FIG. 2. FIG. 1 shows a top view of an electronic device 10 according to a first embodiment of the invention. FIG. 2 shows a cross-sectional view of the electronic device 10 of FIG. 1 viewed along a dotted line A-A′. The electronic device 10 includes a display panel 110, a transparent glass substrate 120, an inductive charge element 130 and a power storage element 140 (the display panel 110 and the transparent glass substrate 120 are illustrated in FIG. 2, and the power storage element 140 is illustrated in FIG. 1). The display panel 110 for displaying the frame is realized by such as a liquid crystal display panel. The transparent glass substrate 120 covers the display panel 110 and is used as a protective board for the display panel 110 to avoid the display panel 110 being scratched. The transparent glass substrate 120 is a substrate of a display device or a touch panel, or a cover lens board. The inductive charge element 130 receives a power by way of wireless sensing. In the present embodiment, the inductive charge element 130 is disposed on the transparent glass substrate 120 which is used as a protective board. The power storage element 140 electrically connected to the inductive charge element 130 for storing the power is realized by such as a nickel-cadmium battery or a Ni—MH battery.

The inductive charge element 130 includes a transparent conductive coil 131, a transparent protective layer 132, a transparent wire 134, an insulation layer 135 and two pads 133. The transparent conductive coil 131 is disposed on the transparent glass substrate 120 and is realized by such as an ITO conductive coil. As indicated in FIG. 1, the transparent conductive coil 131 is a spiral structure in the embodiment. As indicated in FIGS. 1 and 2, the insulation layer 135 covers a portion of the transparent conductive coil 131.

In the present embodiment of the invention, the transparent conductive coil 131 has a terminal point a1 near the center. The terminal point a1 is electrically connected to the transparent wire 134, which is disposed on the insulation layer 135 and extended to be electrically connected to the power storage element 140. The insulation layer 135 is used to avoid the contact between the transparent wire 134 and the transparent conductive coil 131 which would otherwise result in short-circuiting. The transparent protective layer 132 covers the transparent conductive coil 131 and the transparent wire 134 to protect the transparent conductive coil 131 and the transparent wire 134.

The pads 133 are electrically connected to two ends of the transparent conductive coil 131 respectively. The power storage element 140 is electrically connected to the pads 133. The transparent protective layer 132 has two openings 132a for exposing the pads 133.

The transparent glass substrate 120 of the present embodiment is a protective board for the display panel 110. The inductive charge element 130 is disposed on one side of the transparent glass substrate 120 away from the display panel 110. However, the position of the inductive charge element 130 is not for limiting the scope and spirit of the invention, and the inductive charge element 130 can also be disposed on one side of the transparent glass substrate 120 near the display panel 110. Thus, the inductive charge element 130 can be directly disposed on a protective board used as the display panel 110, so that the user can perform charging conveniently without using any external inductive charge element.

### Second Embodiment

Referring to FIG. 3, a cross-sectional view of an electronic device 20 according to a second embodiment of the invention. The difference between the electronic device 20 of the second embodiment and the electronic device 10 of the first embodiment is the inductive charge element 130 disposed on the transparent glass substrate 210 having a touch circuit 250 instead of being disposed on a transparent glass substrate 220 used as a protective board for the display panel 110, and the similarities are not repeated here.

As indicated in FIG. 3, the touch circuit 250 and the inductive charge element 130 are disposed on two opposite lateral surfaces of the transparent glass substrate 210. In an embodiment, the touch circuit 250 and the inductive charge element 130 can also disposed on the same lateral surface of the transparent glass substrate 210. In the present embodiment of the invention, the touch circuit 250 is disposed on one side of the transparent glass substrate 210 near the display panel 110 and is realized by a resistive touch circuit with matrix structure. In the present embodiment, the transparent glass substrate 210 can be realized by a flexible glass or a hard glass. Thus, the touch circuit 250 and the inductive charge element 130 can be completed in the same manufacturing process, and the manufacturing cost of the inductive charge element 130 can be further reduced.

In the present embodiment, the transparent glass substrate 220 used as a protective board for the display panel 110 is disposed on one side of the transparent glass substrate 210 away from the display panel 110.

### Third Embodiment

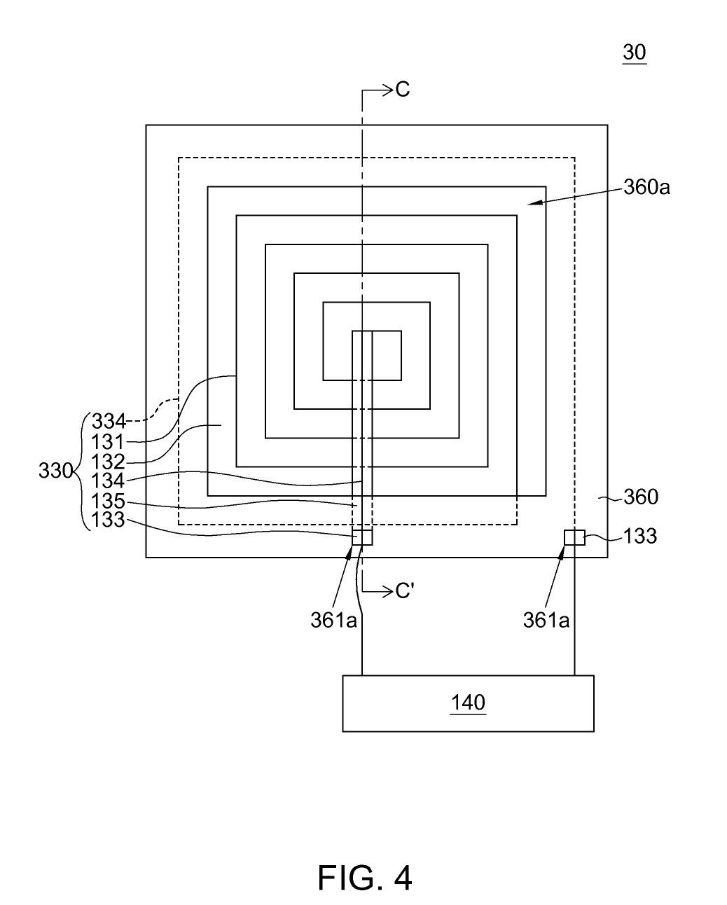

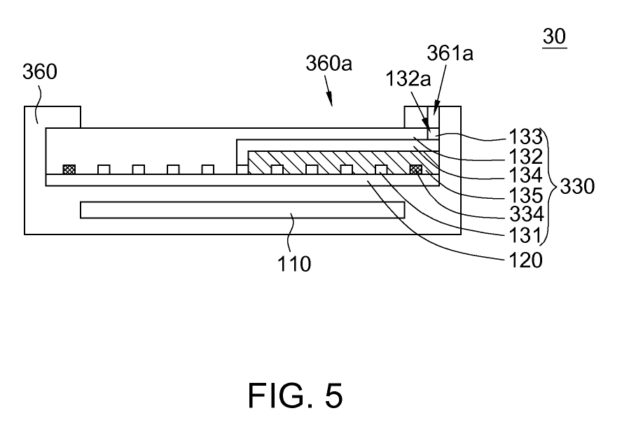

Refer to FIG. 4 and FIG. 5. FIG. 4 shows a top view of an electronic device 30 according to a first embodiment of the invention. FIG. 5 shows s a cross-sectional view of the electronic device 30 of FIG. 4 viewed along a dotted line C-C′. The difference between the electronic device 30 of the third embodiment and the electronic device 10 of the first embodiment is the inductive charge element 330 further includes a metal conductive coil 334. The casing 360 of the electronic device 30 has an opening 360a for exposing the display panel 110. The casing 360 further has an opening 361a corresponding to the opening 132a, so that the opening 132a is connected to the opening 361a for exposing the pad 133. The metal conductive coil 334 is disposed on the transparent glass substrate 120 and connected to the transparent conductive coil 131, and spirally surrounds the peripheral of the transparent conductive coil 131. The transparent conductive coil 131 is exposed by the opening 360a. The casing 360 shields the metal conductive coil 334. In the present embodiment, the metal conductive coil 334 and the transparent conductive coil 131 are disposed on the same lateral surface of the transparent glass substrate 120. Thus, the metal conductive coil 334 being shielded by the casing 360 can provide better conductive efficiency so as to increase the charging efficiency.

According to the characteristics of the embodiments disclosed above, an electronic device can achieve wireless charging by disposing a transparent conductive coil, such as an ITO conductive coil, on a transparent glass substrate without using extra element or connecting to an external charger, wherein the transparent glass substrate can be realized by a display substrate, a touch panel substrate or a lens board. The design of disposing a transparent conductive coil on a transparent glass substrate does not occupy any extra space or add additional weight, and the spirit and scope of the invention are applicable to mobile phone screen, camera screen, display screen, MP3 screen, or screens of other 3C products.

While the invention has been described by way of example and in terms of the preferred embodiment(s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. An electronic device, comprising:
a transparent glass substrate;
an inductive charge element, comprising:
a transparent conductive coil disposed on the transparent glass substrate, wherein the transparent conductive coil is a spiral structure; and
a transparent protective layer covering the transparent conductive coil; and
a power storage element electrically connected to the inductive charge element.

2. The electronic device according to claim 1, further comprising a display panel, wherein the transparent glass substrate covers the display panel.

3. The electronic device according to claim 2, wherein the electronic device further comprises a casing having an opening for exposing the display panel, and the inductive charge element further comprises:
a metal conductive coil disposed on the transparent glass substrate and connected to the transparent conductive coil, wherein the metal conductive coil spirally surrounds the peripheral of the transparent conductive coil, the transparent conductive coil is exposed by the opening, and the metal conductive coil is shielded by the casing.

4. The electronic device according to claim 3, wherein the metal conductive coil and the transparent conductive coil are disposed on the same lateral surface of the transparent glass substrate.

5. The electronic device according to claim 2, wherein the transparent glass substrate is a protective board for the display panel.

6. The electronic device according to claim 2, wherein the inductive charge element is disposed on one side of the transparent glass substrate away from the display panel.

7. The electronic device according to claim 1, further comprising:
a touch circuit disposed on the transparent glass substrate, wherein the touch circuit is a matrix structure.

8. The electronic device according to claim 7, wherein the touch circuit and the transparent conductive coil are disposed on two opposite lateral surfaces of the transparent glass substrate.

9. The electronic device according to claim 7, wherein the touch circuit is a resistive touch circuit.

10. The electronic device according to claim 1, wherein the transparent glass substrate is a substrate of a display device or a touch panel, or a cover lens board.

11. The electronic device according to claim 1, wherein the materials of the transparent conductive coil comprise indium tin oxide (ITO).

12. The electronic device according to claim 1, wherein the inductive charge element further comprising:
two pads electrically connected to two ends of the transparent conductive coil respectively, wherein the power storage element is electrically connected to the pads which are exposed by two openings of the transparent protective layer.
